(19) United States
(12) Patent Application Publication
(10) Pub. No.: US 2025/0282250 A1
(43) Pub. Date: Sep. 11, 2025

(54) ELECTRIC VEHICLE CHARGER PERFORMANCE INSPECTION SYSTEM

(71) Applicant: YJ TECHNOLOGY CO., LTD., Hwaseong-si (KR)

(72) Inventors: Won-Min LEE, Hwaseong-si (KR); Tae-Hoon JEONG, Hwaseong-si (KR); Jeong-Hwan SEOL, Hwaseong-si (KR); Seung-Hyeon NAM, Osan-si (KR)

(21) Appl. No.: 19/216,736

(22) Filed: May 23, 2025

Related U.S. Application Data
(63) Continuation of application No. PCT/KR2023/017473, filed on Nov. 3, 2023.

(30) Foreign Application Priority Data
Nov. 24, 2022 (KR) 10-2022-0159569

(51) Int. Cl. B60L 53/66; G01R 31/40; G06F 30/20

(52) U.S. Cl. CPC B60L 53/665; G01R 31/40; G06F 30/20

(57) ABSTRACT

Provided is an electric vehicle charger performance inspection system enabling inspection of the performance of a charger for charging an electric vehicle with a DC power source, comprising: a simulator generating a control signal for simulating a failure; a failure simulation module comprising a failure simulation circuit unit for causing switches to operate by the control signal generated, and an insulation failure simulation circuit unit for causing the switches to operate by the control signal of the simulator; a load module comprising a resistor load bank including multiple resistors connected to the DC power source, and switches operated by a signal of the simulator to cause the multiple resistors to be connected to or blocked from a DC power line; and a path switching main module wherein inlets having plugs of one or more types of chargers inserted thereinto, and a connector connected to the load module are installed.

### TECHNICAL FIELD

The present invention relates to an electric vehicle charger performance inspection system capable of inspecting the performance of a charger for charging an electric vehicle using DC power.

### BACKGROUND ART

Korean Patent Registration No. 10-2288798 (Title of the invention: Electric vehicle charger simulation test device) (hereinafter, referred to as “related art”) filed and registered by the present applicant discloses an electric vehicle electrical simulation test device capable of performing an “electric vehicle charger simulation test” for simulating and testing a situation in which an electric vehicle is connected to a charger to enable periodic performance test and maintenance of the electric vehicle charger and an “electric vehicle battery simulation load test” for simulating and testing a situation in which a battery of the electric vehicle is connected.

However, the related art has problems in which the electric vehicle charger simulation test device is not suitable for use as an inspection device for inspecting a charger chargeable with a high-pressure DC.

In addition, the related art has a problem that the electric vehicle charger simulation test device may not be applied in the field to inlets having mutually different structures that are variously used in chargers.

### DISCLOSURE

### Technical Problem

To solve the problems, an object of the present invention is to provide a charger performance inspection system capable of testing insulation breakdown that may occur during high-voltage DC charging. In addition, another object of the present invention is to provide a charger performance inspection system having a wide application range capable of connecting both types of inlets of chargers installed in the

### FIELD

In addition, still another object of the present invention is to provide a charger performance inspection system capable of performing a load test by selecting a wide range of load capacity using a load module of 0 to 200 Kw.

### Technical Solution

To solve the above technical problem, the technical solution relates to an electric vehicle charger performance inspection system for testing a performance of an electric vehicle charger that charges an electric vehicle by supplying DC power to the electric vehicle, in which the electric vehicle charger performance inspection system includes: a simulator configured to generate a control signal that controls a connected control target and simulates a failure; a failure simulation module including a failure simulation circuit unit configured to simulate a failure state by allowing switches to operate by a control signal generated according to a sequence stored in the simulator, and an insulation failure simulation circuit unit configured to generate a result corresponding to insulation breakdown by allowing the switches to operate according to the control signal of the simulator; a load module including a resistor load bank that includes a plurality of resistors connected to the DC power to perform a load test of the charger and switches driven by a signal of the simulator such that the plurality of resistors are connected to or disconnected from a DC power line; and a line switching main module where inlets into which a plug of at least one type of the charger is inserted and connectors connected to the load module are installed.

In addition, according to the present invention, the insulation failure simulation circuit unit may further include a plurality of resistors and a plurality of capacitors installed between DC+ and DC− of the DC power line and a ground (PE), and switches operated by control signals from the simulator such that the plurality of resistors and the plurality of capacitors are connected to or disconnected from the DC+ and DC−, and the simulator may allow a specific resistor or a capacitor to be connected between the DC+ and the PE and between the DC− and the PE, recognize an insulation breakdown state when a charging current value compared with a preset value exceeds the preset value, determine that the charger is normal when the charger performs charging cut-off, and determine that the charger is abnormal when the charger does not perform charging cut-off in the insulation breakdown state.

In addition, according to the present invention, the load module may have a converter configured to generate a reference voltage by receiving power from an external independent power supply module, and drive the converter such that the DC power is linked with the reference value when the DC power is reduced to a preset voltage or less.

In addition, according to the present invention, the line switching main module may further include an interlock circuit connected to the inlets so that only power of a plug connected to a specific inlet is supplied to the load module and the failure simulation module.

### Advantageous Effects

According to the present invention having the technical problem and the technical solution, it is possible to significantly improve safety by simulating a failure simulation test by a sequence of a simulator in a charger charged with DC power and an insulation failure that may occur at a high voltage and a large capacity.

In addition, it is possible to implement a countermeasure against a low voltage that may be initially generated during a load test, thereby smoothly performing the load test.

In addition, inlets for selectively inserting various types of plugs, which are connected to a plurality of chargers, may be provided so as to perform a test, and an interlock circuit may be provided so as to inactivate another inlet when a specific inlet is activated, thereby enhancing safety.

### DESCRIPTION OF DRAWINGS

FIG. 1 is a configuration view for explaining an overall configuration of the present invention.

FIG. 2 is a failure simulation circuit of the present invention.

FIG. 3 is a view showing a sequence of a simulator applied to the failure simulation circuit of the present invention.

FIG. 4 is a view of an insulation failure simulation circuit of the present invention.

FIG. 5 is a front view of a line switching main module of the present invention.

FIG. 6 is a view of an interlock circuit of an inlet of the present invention.

FIG. 7 is a view of a specific circuit of a load module of the present invention.

### BEST MODE

Hereinafter, the present invention will be described in detail with reference to the accompanying drawings.

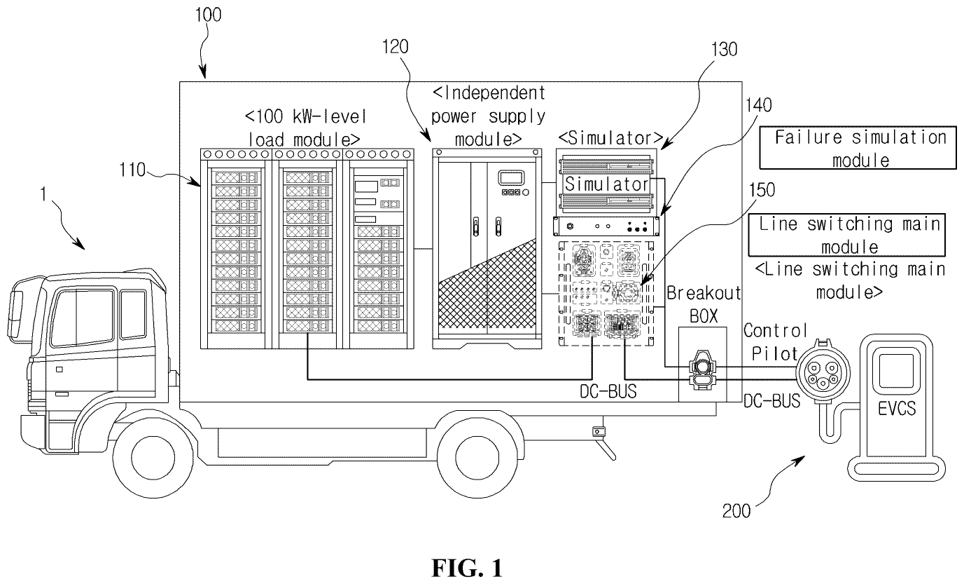

FIG. 1 is a configuration view for explaining an overall configuration of the present invention.

An electric vehicle charger performance inspection system 100 according to the present invention is preferably configured as a mobile performance inspection system mounted in a vehicle 1 such that an electric vehicle charger 200 (hereinafter, referred to as a “charger”) may be quickly and conveniently moved to a site where the electric vehicle charger 200 is installed.

The electric vehicle charger performance inspection system 100 installed in the vehicle 1 includes: a simulator 130 that is in charge of an operating system (O.A), generates a control signal for control objects, is connected to the charger 200 through a control pilot (CP) to transmit and receive the control signal, and generates a simulation signal for simulating a failure according to a stored sequence; a failure simulation module 140 that simulates the failure according to a signal of the simulator 130; a line switching main module 150 that includes a CCS1-type inlet into which a CCS1-type plug of the charger is inserted and a CCS2-type inlet into which a CCS2-type plug is inserted, and has a load module connection connector installed therein; a load module 110 that forms a specific resistance value according to the control signal of the simulator 130; and an independent power supply module 120 that is configured as an uninterruptible power supply device.

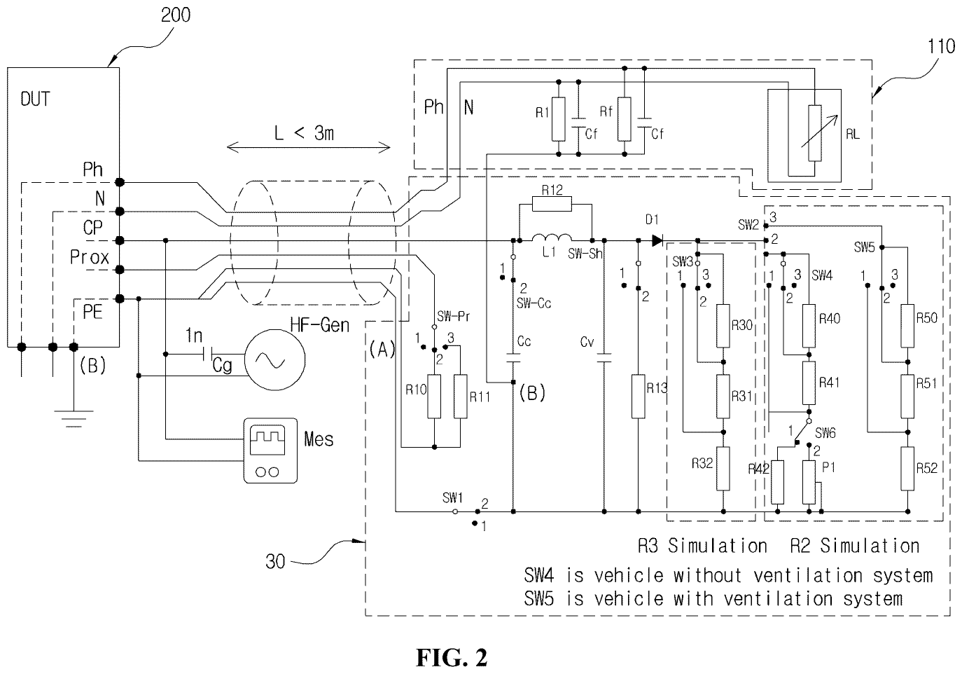

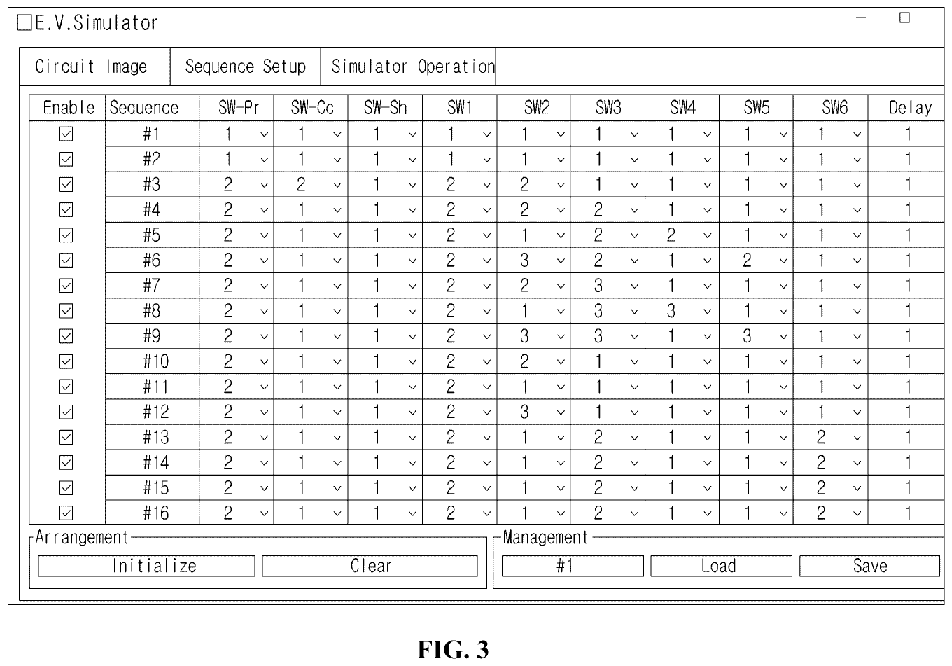

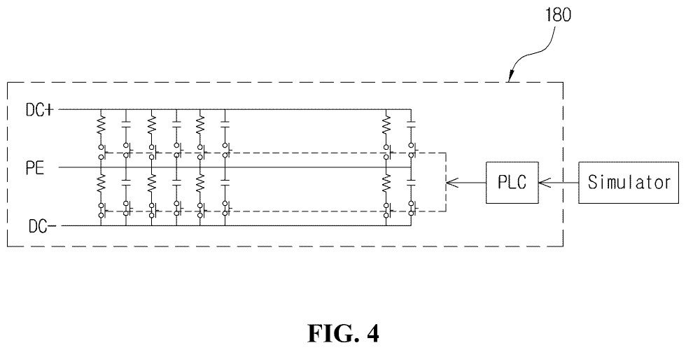

FIG. 2 is a view of a failure simulation circuit of the present invention, FIG. 3 is a view showing a sequence of a simulator applied to the failure simulation circuit of the present invention, and FIG. 4 is a view of an insulation failure simulation circuit of the present invention.

According to the present invention, the failure simulation module 140 includes a simulation switching circuit unit 170 that includes a switch operated by the control signal of the simulator 130 according to a sequence shown in FIG. 3, and an insulation failure simulation circuit unit 180 that tests a resistor insulation failure simulation operation and capacitor insulation failure simulation operation shown in FIG. 4.

As shown in FIGS. 1 and 2, in the charger 200, the load module 110, the simulation switching circuit unit 170, and the insulation failure simulation circuit unit 180 are connected in parallel, and the load module 110, the simulation switching circuit unit 170, and the insulation failure simulation circuit unit 180 perform a control operation according to the control signal of the simulator 130.

In addition, a cable is drawn out from the charger 200 and a plug of an end portion is coupled to an inlet of the line switching main module 150, so that DC power is supplied to the load module 110, the simulation switching circuit unit 170, the insulation breakdown simulation circuit unit 180, and the simulator 130.

In the charger 200, a terminal Ph of the electric cable refers to a power line terminal, a terminal N refers to a neutral line terminal, a terminal Cp refers to a control pilot transmission line terminal, a terminal Prox refers to an operation detection terminal of a proximity detection switch terminal, which detects coupling of the plug of the cable and an inlet of a simulation test device, and a terminal PE refers to a terminal that detects grounding of a chassis.

The simulation switching circuit unit 170 is implemented on a circuit board of the simulation test device in which a simulation circuit, switches that may be switched according to resistance values defined by electric vehicle species that may be connected to the charger 200, and error occurrence switches that intentionally generate a failure are installed, and the description of each switch is shown in Table 1 below.

TABLE 1

| | | State | | |
|---|---|---|---|---|
| Switch | Description | 1 | 2 | 3 |
| SW-Pr | Depending on the charging cable | Failure | Capacity: 20 | Capacity: 32 A |
| | connector with a proximity | | A | |
| | detection switch, it needs to | | | |
| | determine a current capacity of | | | |
| | the cable assembly and operates | | | |
| | in an open mode upon failure | | | |
| SW-Cc | Regarding the cable capacity | Open | Case A | — |
| | (when cables of case A and case | | Case B | |
| | B are used, it does not need to be | | | |
| | recognized as a failure in state 2) | | | |
| SW-Sh | Control pilot short circuit test | Normal | Short circuit | — |
| | (test for checking failure | | (failure) | |
| | detection due to short circuit for | | | |
| | the control pilot circuit) | | | |
| SW1 | Detection of an abnormal state | failure | Normal | — |
| | of system grounding | | | |
| SW2 | Normal supply of charging | Input of a minimum | Ax or Bx step | Input of a minimum |
| | power to the electric vehicle | test value, a process | | test value, a process |
| | through a charger | value, and a | | value, and a |
| | | maximum test value | | maximum test value |
| | | into the electric | | into the electric |
| | | vehicle that does not | | vehicle that requires |
| | | require ventilation | | ventilation |
| SW3 | Permanent resistance value of the | Minimum test value | Process value | Maximum test value |
| | electric vehicle (it is determined | | | |
| | to be used by selecting a unique | | | |
| | value for each electric vehicle | | | |
| | manufacturer) | | | |
| | R3 Simulation of a typical control | | | |
| | pilot circuit | | | |
| SW4 | R2 simulation while interworking | Minimum test value | Process value | Maximum test value |
| | with R2 simulation (SW6) of a | | | |
| | typical control pilot circuit of the | | | |
| | electric vehicle that does not | | | |
| | require ventilation when SW2 is | | | |
| | switched to state 1, fix SW6 to | | | |
| | state 1 at normal times | | | |
| SW5 | R2 Simulation of a typical | Minimum test value | Process value | Maximum test value |
| | control pilot circuit of the electric | | | |
| | vehicle that requires ventilation | | | |
| | when SW2 is switched to state 3 | | | |
| SW6 | Fixed to State 1 upon R2 | F2 Resistance value | Hysteresis test | — |
| | simulation of a typical control | simulation | of charger | |
| | pilot circuit of an electric vehicle | | power supply | |
| | that does not require ventilation | | | |
| | when SW2 is switched to state 1. | | | |
| | When switching to state 2, it is | | | |
| | used as a switching switch for a | | | |
| | hysteresis test of an electric | | | |
| | vehicle charger. | | | |

In this case, since SW4 in the simulation of a resistor R2 relates to a vehicle without a ventilation system and SW5 is a simulation resistance terminal for the vehicle with the ventilation system, the switch SW2 for initiating charging power needs to be connected to a contact point 1 in order to simulate charging of the vehicle without the ventilation system and the switch SW2 needs to be connected to a contact point 3 in order to simulate charging of the vehicle with the ventilation system. In order to change a type of simulation resistance of a resistor R3 according to a type of the vehicle, the switch SW4 is brought into contact with the contact points 1, 2, and 3, and the switch SW6 is brought into contact with the contact points 1 and 2. The contact point may be automatically changed according to a simulation sequence of FIG. 3 stored in the simulator 130, or may be manually changed by a user.

Since the charger 200 is charged by high-voltage DC, the insulation failure test is necessarily accompanied, and thus the insulation test is performed by the insulation failure simulation circuit unit 180 of FIG. 4. That is, in a normal state, the charger 200 needs to perform a cut-off operation within a set time to protect the charger 200 and the electric vehicle upon insulation breakdown. However, since the insulation test may not be directly performed by using the electric vehicle in the site, the insulation failure simulation circuit unit 180 performs the insulation failure test instead.

In the insulation failure simulation circuit unit 180, DC+ and DC− are power lines connected to DC+ and DC− of the inlet of the switching main module 150, PE is a ground line connected to the PE terminal of the inlet, the charger 200 to be tested is coupled to the inlet, and in a case where a preset resistor and a preset capacitor are connected between the DC+ and the PE and between the DC− and the PE, when a charging current of a preset value or more flows, it is considered that insulation breakdown have occurred, and thus no more charging operation needs to be performed from the charger 200.

Accordingly, in FIG. 4, the simulator 130 allows a specific resistor or a capacitor to be connected between the DC+ and the PE and between the DC− and the PE, recognizes an insulation failure state when the charging current value, which is compared with the preset value and is equal to or greater than the preset value, flows, and detects whether the charging current is cut off from the charger 200 so as to perform an insulation failure simulation test for determining that the charger in which the charging current is cut off is normal and determining that the charger is abnormal when the charging current continues to flow.

The insulation failure simulation circuit unit 180 includes a plurality of resistors and capacitors connected between a DC+ line and a PE line, switches operating to turn on/off currents flowing in the elements, and a driving unit (programmable logic controller (PLC)) driven by receiving a driving signal from the simulator 130 to operate the switches, and similarly, the insulation failure simulation circuit unit 180 includes a plurality of resistors and capacitors connected between a DC-line and the PE line, switches operating to turn on/off currents flowing in the elements, and a driving unit (PLC) driven by receiving a driving signal from the simulator 130 to operate the switches.

Therefore, the insulation failure simulation test includes “resistance insulation failure simulation” for simulating insulation breakdown by randomly selecting a resistor between DC+<->PE/DC−<->PE, and “capacitor insulation failure simulation” for simulating insulation breakdown by randomly selecting a capacitor between DC+<->PE/DC−<->PE.

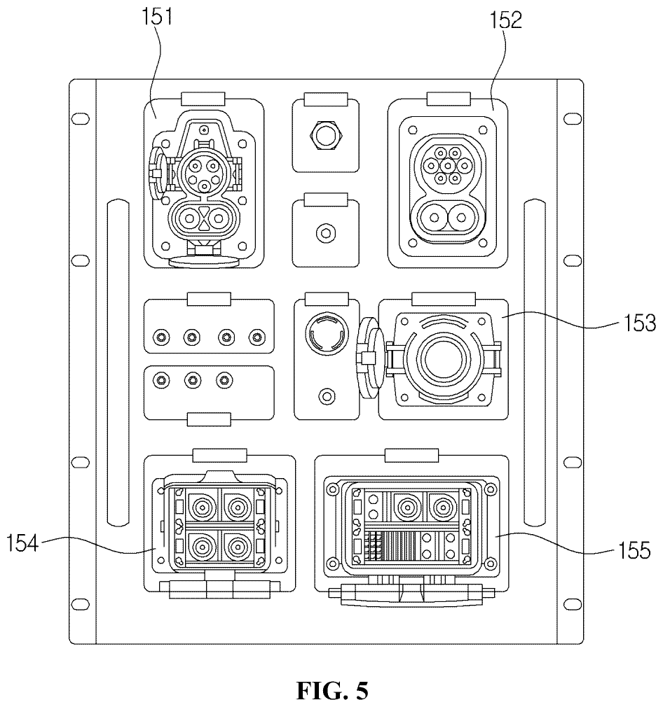

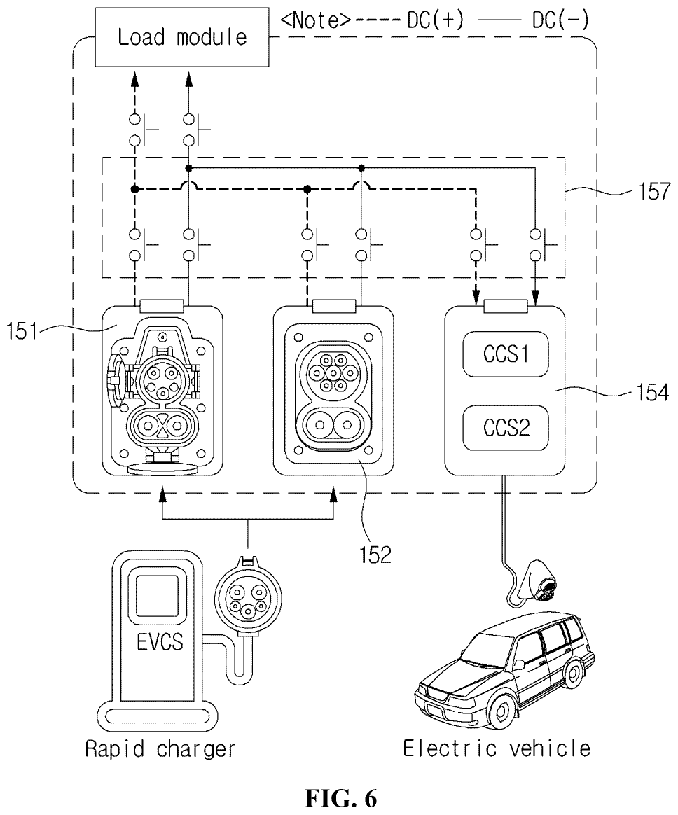

FIG. 5 is a front view of a line switching main module of the present invention, and FIG. 6 is a view of an interlock circuit of an inlet of the present invention.

The line switching main module 150 shown in FIG. 5 includes a CCS1-type inlet 151 into which a plug of the charger 200 is inserted and a CCS2-type inlet 152 into which a plug of the charger 200 is inserted, which are allowed in the standard 61851-23, a ChaDeMo-type inlet into which a plug used in a charger specially manufactured in Japan is inserted, a load connection connector 155 connected to the load module 110, and a gun connection connector 154 to which a gun of the electric vehicle is coupled such that the electric vehicle may be directly tested.

In addition, the CCS1 inlet 151 and the CCS2 inlet 152, which are mainly used, are connected to an interlock circuit 157 shown in FIG. 6 so as not to operate at the same time. That is, the switches driven by the simulator 130 are connected to power lines (+) and (−) output from the inlet 151 and the inlet 152 to the load module 110, and when the switches of output lines of the inlet 151 are operated, the simulator 130 performs an interlock operation that controls the switches of the output lines of the inlet 152 not to be operated or to perform a reverse operation, thereby preventing power from being simultaneously supplied from the two inlets 151 and 152 to the inside.

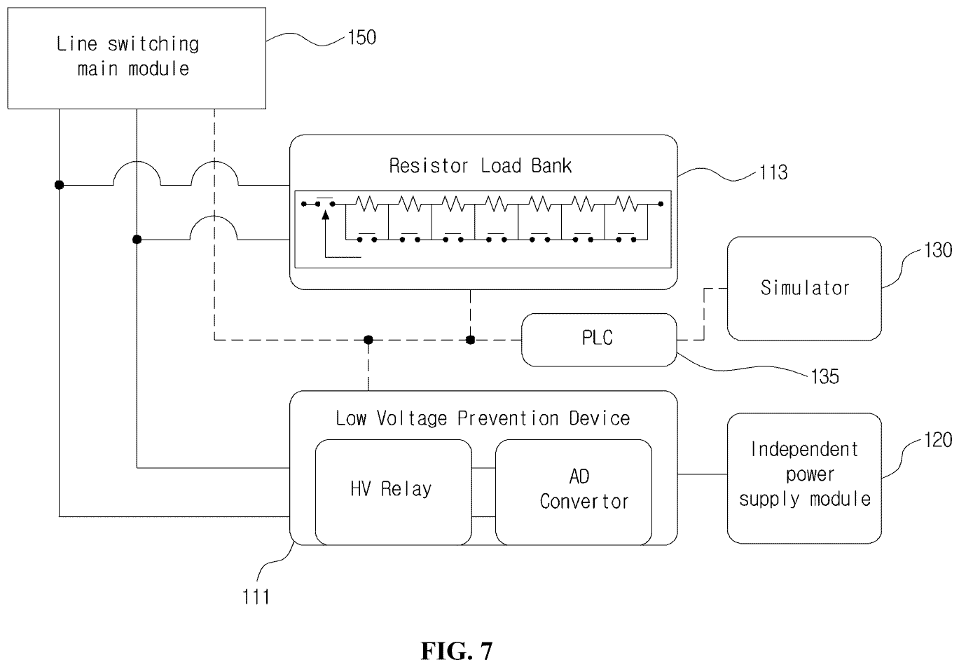

FIG. 7 is a view of a specific circuit of a load module of the present invention.

In order to check whether the output performance of the charger 200 is fully operated at the site where the charger 200 is installed, there are a battery module method, a BACK-to-BACK PCS method, a resistor load bank method, and the like, but the battery module method may be retested only when the battery is charged and the charged battery is discharged after a test, so that it is difficult to apply the battery module method, and the BACK-to-BACK PCS method is used as a power system of KEPCO in the site, so that this method has a problem of field application. Therefore, the load test of the charger 200 is preferably performed by the load module 110 to which a resistor load bank 113 is applied.

The load module 113 includes a resistor load bank 113 including a plurality of resistors connected to DC power supplied from the line switching main module 150 and switches for connecting or disconnecting the resistors to or from the power supply, and an independent power supply module 120 including a PLC that operates the switches of the resistor load bank 113 by receiving a driving signal to generate a set resistance value by operating specific switches from the simulator 130, a low-voltage protection unit 111 that prevents a low-voltage phenomenon occurring at an initial load test, a UPS that supplies a voltage to the low-voltage protection unit 111, and the like.

In the initial stage in which the charger 200 is switched from a connection standby state to a charging state as the load module 110 is inserted thereinto, an instantaneous voltage drop occurs, and when a low-voltage detection device of the charger 200 is operated, the charger 200 no longer supplies power to the resistor load bank 113 and is cut off, and thus no load test may be performed. In order to solve the problem of the DC power cut-off, the low-voltage protection unit 111 is installed to receive the power from the independent power supply module 120 when the charging voltage is reduced to a preset voltage or less when the load module is inserted, and to link the reference voltage with the DC power line, thereby preventing the charger 200 from being cut off anymore.

The low-voltage protection unit 111 for performing the above-described operation includes a converter that receives power from the independent power supply module 120 such as a UPS to generate a reference voltage, and a relay (HV relay) that detects a decrease of a preset voltage or less and drives the converter to supply the power of the converter to the DC power line.

1. An electric vehicle charger performance inspection system for testing a performance of an electric vehicle charger that charges an electric vehicle by supplying DC power to the electric vehicle, the electric vehicle charger performance inspection system comprising:
a simulator configured to generate a control signal that controls a connected control target and simulates a failure;
a failure simulation module including a failure simulation circuit unit configured to simulate a failure state by allowing switches to operate by a control signal generated according to a sequence stored in the simulator, and an insulation failure simulation circuit unit configured to generate a result corresponding to insulation breakdown by allowing the switches to operate according to the control signal of the simulator;
a load module including a resistor load bank that includes a plurality of resistors connected to the DC power to perform a load test of the charger and switches driven by a signal of the simulator such that the plurality of resistors are connected to or disconnected from a DC power line; and
a line switching main module where inlets into which a plug of at least one type of the charger is inserted and connectors connected to the load module are installed.

2. The electric vehicle charger performance inspection system of claim 1, wherein the insulation failure simulation circuit unit further includes a plurality of resistors and a plurality of capacitors installed between DC+ and DC− of the DC power line and a ground (PE), and switches operated by control signals from the simulator such that the plurality of resistors and the plurality of capacitors are connected to or disconnected from the DC+ and DC−, and
the simulator allows a specific resistor or a capacitor to be connected between the DC+ and the PE and between the DC− and the PE, recognizes an insulation breakdown state when a charging current value compared with a preset value exceeds the preset value, determines that the charger is normal when the charger performs charging cut-off, and determines that the charger is abnormal when the charger does not perform charging cut-off in the insulation breakdown state.

3. The electric vehicle charger performance inspection system of claim 1, wherein the load module has a converter configured to generate a reference voltage by receiving power from an external independent power supply module, and drives the converter such that the DC power is linked with the reference value when the DC power is reduced to a preset voltage or less.

4. The electric vehicle charger performance inspection system of claim 1, wherein the line switching main module further includes an interlock circuit connected to the inlets so that only power of a plug connected to a specific inlet is supplied to the load module and the failure simulation module.

5. The electric vehicle charger performance inspection system of claim 1, wherein the electric vehicle charger performance inspection system is movably installed inside a vehicle.
